(19) United States
(12) Patent Application Publication
(10) Pub. No.: US 2025/0223722 A1
(43) Pub. Date: Jul. 10, 2025

(54) SILICON CARBIDE CRYSTAL BOULE AND MANUFACTURING METHOD THEREOF

(71) Applicant: GlobalWafers Co., Ltd., Hsinchu (TW)

(72) Inventor: Ching-Shan Lin, Hsinchu (TW)

(73) Assignee: GlobalWafers Co., Ltd., Hsinchu (TW)

(21) Appl. No.: 18/928,195

(22) Filed: Oct. 28, 2024

Related U.S. Application Data
(60) Provisional application No. 63/619,316, filed on Jan. 10, 2024.

(51) Int. Cl. C30B 29/36; C30B 23/06; C30B 29/60

(52) U.S. Cl. CPC C30B 29/36; C30B 23/06; C30B 29/60

(57) ABSTRACT

A silicon carbide crystal boule includes a flat surface, a truncated cone surface, and an annular curved surface. The annular curved surface connects the flat surface and the truncated cone surface. A width of the silicon carbide crystal boule gradually decreases from a first end of the truncated cone surface connecting the annular curved surface to a second end opposite to the first end.

### CROSS-REFERENCE TO RELATED APPLICATION

This application claims the priority benefit of U.S. application Ser. No. 63/619,316, filed on Jan. 10, 2024. The entirety of the above-mentioned patent application is hereby incorporated by reference herein and made a part of this specification.

### BACKGROUND

### Technical Field

The disclosure relates to a silicon carbide crystal boule and a manufacturing method thereof.

### Description of Related Art

Silicon carbide (SiC) is a semiconductor material with unique and superior properties. In recent years, silicon carbide has received widespread attention and has been widely applied in the field of high-power and high-frequency electronic devices. Compared with traditional silicon (Si) wafers, silicon carbide wafers have higher breakdown electric field, wider energy gap, higher thermal conductivity, and better radiation resistance. Therefore, silicon carbide wafers have significant advantages in some extreme application environments.

Silicon carbide crystals are usually grown using physical vapor transport (PVT), a technique that uses vapor phase transport and deposition to grow crystals. In the PVT method, the raw materials are heated in a high temperature furnace to sublime into a gas phase. Next, by precisely controlling the temperature gradient, silicon carbide in the gas phase gradually deposits on the seed crystal to form large single-crystal silicon carbide crystals, also known as silicon carbide crystal boules. However, the resulting silicon carbide crystal boules usually contain protruding or depressed surfaces that need to be smoothed before cutting the silicon carbide crystal boules to obtain silicon carbide wafers, and material loss thereby occurs. Moreover, these surface protrusions or depressions may lead to high residual stress in the silicon carbide crystal boules. Consequently, the silicon carbide wafers manufactured subsequently may be warped to varying degrees.

### SUMMARY

The disclosure provides a silicon carbide crystal boule and a manufacturing method thereof capable of improving the problem of protrusions on the surface of the silicon carbide crystal boule.

At least one embodiment of the disclosure provides a manufacturing method of a silicon carbide crystal boule, and the manufacturing method includes the following steps. A raw material containing carbon and silicon elements and a seed crystal located above the raw material are provided in a furnace body of a crystal growth furnace system. A first surface of the seed crystal faces the raw material. The raw material is heated. A portion of the raw material is gasified and then transferred to the first surface of the seed crystal and a sidewall of the seed crystal to form a silicon carbide material on the seed crystal to form a growth body including the seed crystal and the silicon carbide material. The growth body grows in a radial direction perpendicular to the sidewall of the seed crystal and an axial direction perpendicular to the first surface of the seed crystal. During a growth process of the growth body, the growth body has an axial temperature gradient in the axial direction, and the growth body has a radial temperature gradient in the radial direction. A ratio of the axial temperature gradient to the radial temperature gradient is 0.3 to 0.8. The raw material is cooled to obtain the grown growth body. The grown growth body is the silicon carbide crystal boule. The silicon carbide crystal boule includes a flat surface facing the raw material, a truncated cone surface located on a side surface, and an annular curved surface connecting the flat surface and the truncated cone surface. A width of the silicon carbide crystal boule gradually decreases from a first end of the truncated cone surface connecting the annular curved surface to a second end opposite to the first end. A vertical distance between a plane where the first end is located and the flat surface is 1 mm to 5 mm.

At least one embodiment of the disclosure further provides a silicon carbide crystal boule including a flat surface, a truncated cone surface, and an annular curved surface. The annular curved surface connects the flat surface and the truncated cone surface. A width of the silicon carbide crystal boule gradually decreases from a first end of the truncated cone surface connecting the annular curved surface to a second end opposite to the first end. A vertical distance between a plane where the first end is located and the flat surface is 1 mm to 5 mm.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A and FIG. 1B are schematic diagrams of manufacturing a silicon carbide crystal boule using a crystal growth furnace system according to an embodiment of disclosure.

FIG. 2A is a schematic cross-sectional view of the silicon carbide crystal boule according to an embodiment of the disclosure.

FIG. 2B is a schematic top view of the silicon carbide crystal boule according to an embodiment of the disclosure.

FIG. 3 is a schematic cross-sectional view of the silicon carbide crystal rod according to an embodiment of the disclosure.

FIG. 4 is a cross-sectional schematic view of cutting the silicon carbide crystal rod into a plurality of silicon carbide wafers according to an embodiment of the disclosure.

FIG. 5 is a schematic view of a furnace body and an external heating module of the crystal growth furnace system according to an embodiment of the disclosure.

### DESCRIPTION OF THE EMBODIMENTS

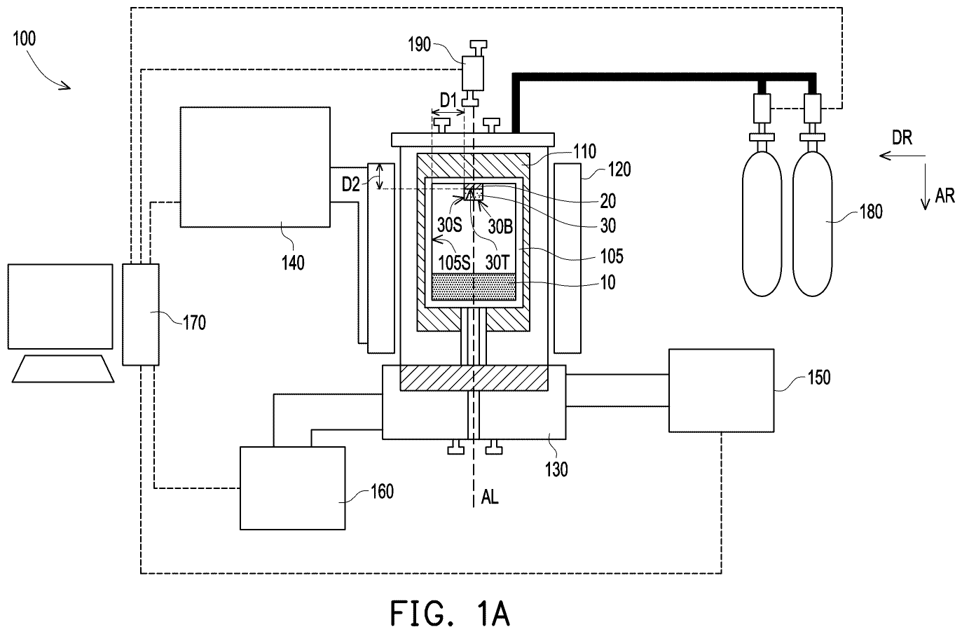

FIG. 1A and FIG. 1B are schematic diagrams of manufacturing a silicon carbide crystal boule using a crystal growth furnace system 100 according to an embodiment of disclosure. With reference to FIG. 1A, the crystal growth furnace system 100 includes a crucible 105, a furnace body 110, an external heating module 120, a power supply 140, a first driving device 150, a second driving device 160, a control device 170, a gas supply device 180, and a thermometer 190.

The external heating module 120 is electrically connected to the power supply 140. The external heating module 120 includes, for example, an induction coil. The crucible 105 is disposed in the furnace body 110, and the furnace body 110 is movably disposed in the external heating module 120 and connected to the gas supply device 180 through a gas pipe. The first driving device 150 drives the furnace body 110 to move along an axis AL, and the second driving device 160 drives the furnace body 110 to rotate along the axis AL. The control device 170 is electrically connected to the power supply 140, the first driving device 150, the second driving device 160, the gas supply device 180, and the thermometer 190.

The furnace body 110 is movably disposed in the external heating module 120. In some embodiments, the control device 170 may control the operation of the first driving device 150 and the second driving device 160 simultaneously or separately, so that the furnace body 110 moves and/or rotates in the external heating module 120. The movement and rotation of the furnace body 110 may be performed simultaneously or separately.

In the embodiments of the disclosure, the furnace body 110 of the crystal growth furnace system 100 may move up and down relative to the external heating module 120 and may also rotate relative to the external heating module 120. With such a design, the furnace body 110 may be heated evenly, so that the crystals in the furnace body 110 are heated evenly, and crystal boules with improved quality are thereby obtained.

In some embodiments, the external heating module 120 is a heating coil assembly. In some embodiments, the furnace body 110 includes a heat insulating layer, so that the temperature inside the furnace body 110 may be accurately controlled. A seed crystal carrier 20 is disposed in the furnace body 110 for fixing a seed crystal 30.

In a manufacturing method of a silicon carbide crystal boule, a raw material 10 including carbon and silicon elements and the seed crystal 30 located above the raw material 10 are placed in the furnace body 110. For instance, the raw material 10 may be silicon carbide powder, which is placed at a bottom portion of the furnace body 110 as a solid sublimation source, and the seed crystal 30 is placed at a top portion of the furnace body 110. In some embodiments, the seed crystal 30 may be fixed on the seed crystal carrier 20 via an adhesive layer. A material of the seed crystal 30 includes silicon carbide. For instance, the seed crystal 30 may be 6H silicon carbide or 4H silicon carbide. In other embodiments, the seed crystal 30 may include both 6H silicon carbide and 4H silicon carbide.

A first surface 30B of the seed crystal 30 faces the raw material 10, and a sidewall 30S of the seed crystal 30 faces an inner sidewall 105S of the crucible 105.

Next, the furnace body 110 and the raw material 10 are heated by the external heating module 120. A silicon carbide material is formed on the seed crystal 30 by physical vapor transport (PVT) to form a growth body 40 including the seed crystal 30 and the silicon carbide material, as shown in FIG. 1B. The seed crystal 30 receives the raw material 10 solidified from the gaseous state and forms a gradually growing growth body 40 until the growth body 40 grows to a desired size.

With reference to FIG. 1A and FIG. 1B, in the abovementioned physical vapor transport heating process, the growth body 40 grows in a radial direction DR of the sidewall 30S of the vertical seed crystal 30 and in an axial direction AR of the first surface 30B of the vertical seed crystal 30. During the growth process, the growing body 40 has an axial temperature gradient (ΔTz) in the axial direction AR, and the growing body 40 has a radial temperature gradient (ΔTx) in the radial direction DR. In some embodiments, the axial temperature gradient (ΔTz) may also refer to the temperature gradient of the seed crystal 30 or the growth body 40 in a thickness direction. The radial temperature gradient (ΔTx) may also refer to the temperature gradient of the seed crystal 30 or the growth body 40 in a horizontal direction perpendicular to the thickness direction thereof.

In the embodiments of the disclosure, the problem of protrusions on a surface of the silicon carbide crystal boule is improved by adjusting a ratio (ΔTz/ΔTx) of the axial temperature gradient (ΔTz) to the radial temperature gradient (ΔTx) of the growth body 40. In a preferred embodiment, the ratio (ΔTz/ΔTx) of the axial temperature gradient (ΔTz) to the radial temperature gradient (ΔTx) is 0.3 to 0.8. When the ratio (ΔTz/ΔTx) is less than 0.3, a growth rate of the growth body 40 becomes slow, a size of the resulting crystal boule is excessively small, and the process is inefficient. When the ratio (ΔTz/ΔTx) is greater than 0.8, the growth rate of the growth body 40 is excessively fast, resulting in poor quality of the crystal boule finally obtained.

In some embodiments, in order to better control the axial temperature gradient (ΔTz) and the radial temperature gradient (ΔTx), a distance D2 between a top end of the external heating module 120 and a second surface 30T of the seed crystal 30 opposite to the first surface 30B is less than 80 mm. If the distance D2 is excessively large (e.g., greater than 80 mm), an edge of the crucible 105 is easily affected by the external heating module 120. When the temperature is excessively high, it may be more difficult for the silicon carbide material to be deposited on the sidewall of the growth body 40 close to the crucible 105, resulting in a convex structure of the growth body 40 that is thick in the middle and thin on the periphery.

In some embodiments, when the physical vapor transport is performed (i.e., during the growth process of the growth body 40), a nitrogen concentration of the growth body 40 is increased to optimize the uniformity of the resistivity of the resulting silicon carbide crystal boule.

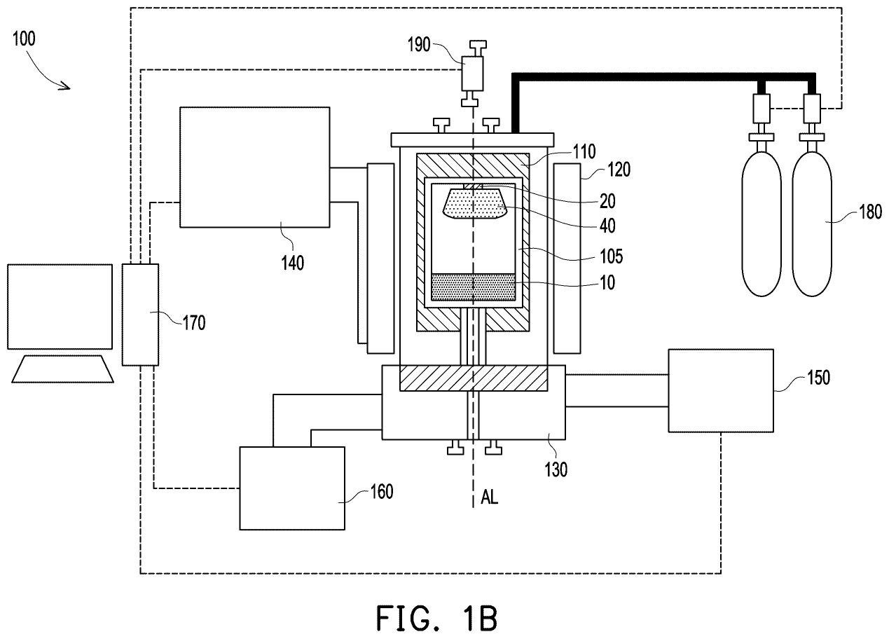

After the growth body 40 grows to the desired size, the raw material 10 is cooled to obtain the grown growth body 40. The grown body 40 is a desired silicon carbide crystal boule 50, as shown in FIG. 2A and FIG. 2B. In some embodiments, the silicon carbide crystal boule may have different crystal structures depending on the crystal orientation of the single crystal seed used. For instance, the silicon carbide crystal boule 50 includes 4H-silicon carbide, 6H-silicon carbide, etc. Both 4H-silicon carbide and 6H-silicon carbide belong to the hexagonal crystal system.

With reference to FIG. 1B, FIG. 2A, and FIG. 2B, the silicon carbide crystal boule 50 includes a flat surface 40B facing the raw material, a truncated cone surface 40S located on a side surface, an annular curved surface 40R connecting the flat surface 40B and the truncated cone surface 40S, and a bottom surface 40T opposite to the flat surface 40B. A width of the silicon carbide crystal boule gradually decreases from a first end E1 of the truncated cone surface 40S connecting the annular curved surface 40R to a second end E2 opposite to the first end E1. A maximum distance between the plane (a virtual plane, shown by a dotted line in the figure) where the first end E1 is located and the flat surface 40B is a vertical distance D3. An angle θ is provided between the plane where the first end E1 is located and the annular curved surface 40R. Generally, the larger the vertical distance D3 is, the larger the angle θ is. In some embodiments, the angle θ is between 1 degree and 8 degrees.

In some embodiments, by adjusting the ratio (ΔTz/ΔTx) of the axial temperature gradient (ΔTz) to the radial temperature gradient (ΔTx) of the growth body 40, the vertical distance D3 between the plane where the first end E1 is located and the flat surface 40B may be reduced. For instance, when the ratio (ΔTz/ΔTx) is 0.3 to 0.8, the vertical distance D3 is 1 mm to 5 mm.

Further, a width WD1 of the flat surface 40B and a width WD2 of the annular curved surface 40R are also affected by the ratio (ΔTz/ΔTx). Generally, when a diameter of the silicon carbide crystal boule 50 is constant, an increase in the width WD1 of the flat surface 40B means that the surface of the silicon carbide crystal boule 50 is flatter. Moreover, less material is wasted when the uneven surface of the silicon carbide crystal boule 50 is removed by a subsequent polishing process. In some embodiments, the width WD1 of the flat surface 40B is 6.5 inches to 8 inches. For example, if the diameter of the silicon carbide crystal boule 50 is 200 mm, when the width WD1 of the flat surface 40B is 150 mm, the width WD2 of the annular curved surface 40R is approximately 25 mm. When the width WD1 of the flat surface 40B is 190 mm, the width WD2 of the annular curved surface 40R is approximately 5 mm.

Table 1 shows the vertical distance D3, the angle θ, and the width WD1 of the silicon carbide crystal boule 50 obtained after adjusting the ratio (ΔTz/ΔTx) of the axial temperature gradient (ΔTz) to the radial temperature gradient (ΔTx).

TABLE 1

| | Example 1 | Example 2 | Example 3 | Example 4 | Example 5 | Example 6 |
|---|---|---|---|---|---|---|
| ΔTz/ΔTx | 1 | 0.8 | 0.7 | 0.6 | 0.5 | 0.3 |
| Width WD1 | 6 inches | 6.5 inches | 7 inches | 7.5 inches | 8 inches | 8 inches |
| (mm) | | | | | | |
| Vertical distance | 7 | 5 | 4 | 3 | 2 | 1 |
| D3 (mm) | | | | | | |
| Angle θ | 10 | 8 | 5 | 3 | 2 | 1 |
| (degrees) | | | | | | |

It can be seen from Table 1 that reducing the ratio (ΔTz/ΔTx) is beneficial to shortening the vertical distance D3. In this disclosure, by setting the ratio (ΔTz/ΔTx) within the range of 0.3 to 0.8, both the manufacturing efficiency and the quality of the silicon carbide crystal boule 50 may be taken into consideration. In a preferred embodiment, the ratio (ΔTz/ΔTx) is set in the range of 0.3 to 0.6, and the vertical distance D3 is 1 mm to 4 mm.

In addition, with reference to FIG. 1A and FIG. 2, the distance D2 between the top end of the external heating module 120 and the second surface 30T of the seed crystal 30 opposite to the first surface 30B may also affect the growth quality of the silicon carbide crystal boule 50. Table 2 shows the vertical distance D3 of the silicon carbide crystal boule 50 obtained after adjusting the distance D2 in some embodiments of the disclosure. In Table 2, a negative value of the distance D2 indicates that the top end of the external heating module 120 is higher than the distance of the second surface 30T. A positive value of the distance D2 indicates that the top end of the external heating module 120 is lower than the distance of the second surface 30T.

TABLE 2

| | Example 7 | Example 8 | Example 9 | Example 10 | Example 11 | Example 12 |
|---|---|---|---|---|---|---|
| Distance D2 | −80 | −60 | −50 | −30 | −10 | less than +10 |
| (mm) | | | | | | and greater |
| | | | | | | than −10 |
| Vertical | 7 | 5 | 3 | 4 | 2 | 1 |
| distance D3 | | | | | | |
| (mm) | | | | | | |

It can be seen from Table 2 that when the distance D2 decreases, it is beneficial to reduce the vertical distance D3.

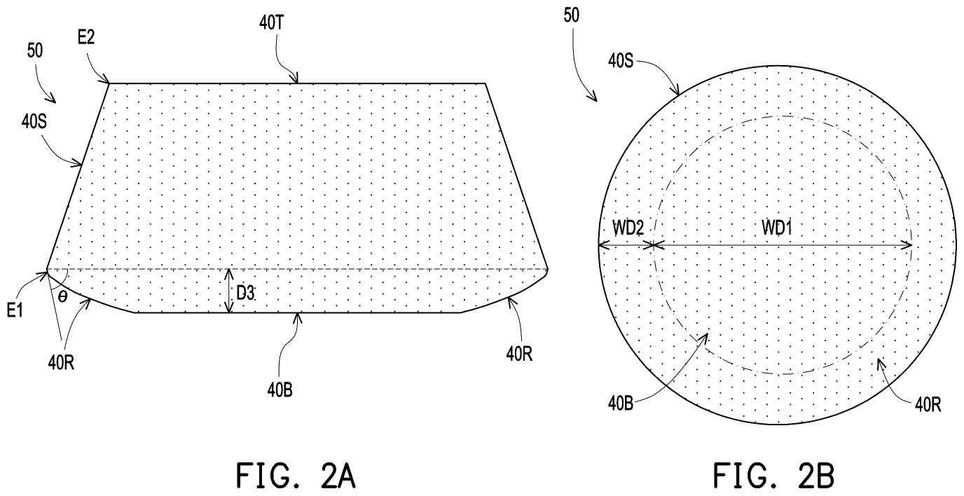

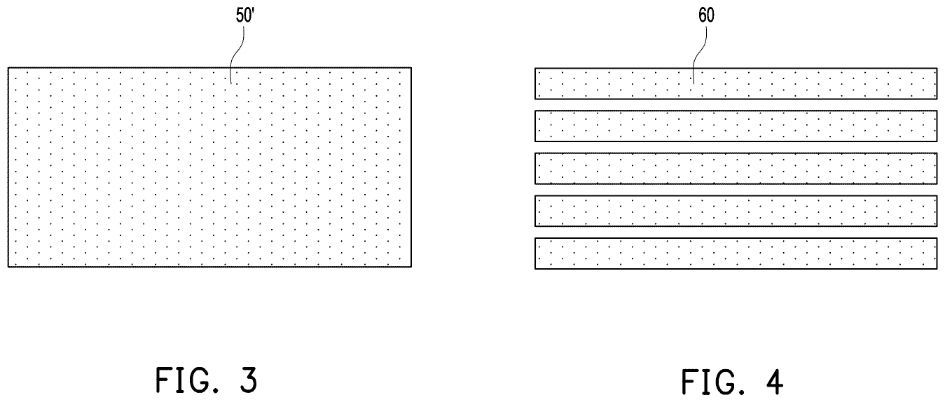

After the silicon carbide crystal boule 50 is formed, the silicon carbide crystal boule 50 is taken out from the crystal growth furnace system 100. Next, a top surface, a bottom surface, and a side surface of the silicon carbide crystal boule 50 are polished to obtain a silicon carbide crystal rod 50′ with uniform width, as shown in FIG. 3. Next, the silicon carbide crystal rod 50′ is cut into a plurality of silicon carbide wafers 60, as shown in FIG. 4.

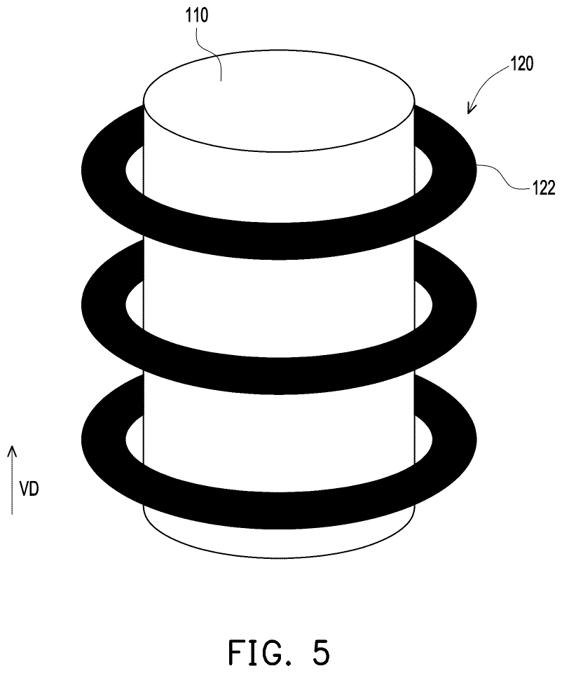

FIG. 5 is a schematic view of a furnace body and an external heating module of the crystal growth furnace system according to an embodiment of the disclosure. For instance, the furnace body 110 and the external heating module 120 in FIG. 1A and FIG. 1B may be as shown in FIG. 5.

With reference to FIG. 5, the external heating module 120 includes a plurality of heating rings 122 stacked in a vertical direction VD. Each heating ring 122 is located at a different horizontal plane. More specifically, each heating ring 122 is a coil, and the coil axes of these coils are parallel to each other. With reference to FIG. 1A and FIG. 5, in some embodiments, a distance D2 between a top end of the topmost one among the heating rings 122 and the second surface 30T of the seed crystal 30 is less than 80 mm in the vertical direction VD.

Such a coil design may be conducive to controlling the axial temperature gradient (ΔTz) and the radial temperature gradient (ΔTx), and a silicon carbide crystal boule with improved quality is obtained.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A manufacturing method of a silicon carbide crystal boule, comprising:
providing a raw material containing carbon and silicon elements and a seed crystal located above the raw material in a furnace body of a crystal growth furnace system, wherein a first surface of the seed crystal faces the raw material;
heating the raw material, wherein a portion of the raw material is gasified and then transferred to the first surface of the seed crystal and a sidewall of the seed crystal to form a silicon carbide material on the seed crystal to form a growth body comprising the seed crystal and the silicon carbide material; wherein the growth body grows in a radial direction perpendicular to the sidewall of the seed crystal and an axial direction perpendicular to the first surface of the seed crystal, during a growth process of the growth body, the growth body has an axial temperature gradient in the axial direction, and the growth body has a radial temperature gradient in the radial direction, wherein a ratio of the axial temperature gradient to the radial temperature gradient is 0.3 to 0.8; and
cooling the raw material to obtain the grown growth body, wherein the grown growth body is the silicon carbide crystal boule, wherein the silicon carbide crystal boule comprises a flat surface facing the raw material, a truncated cone surface located on a side surface of the silicon carbide crystal boule, and an annular curved surface connecting the flat surface and the truncated cone surface, wherein a width of the silicon carbide crystal boule gradually decreases from a first end of the truncated cone surface connecting the annular curved surface to a second end opposite to the first end, and a vertical distance between a plane where the first end is located and the flat surface is 1 mm to 5 mm.

2. The manufacturing method according to claim 1, wherein the crystal growth furnace system comprises:
an external heating module comprising a plurality of heating rings stacked in a vertical direction, each heating ring is located at a different horizontal plane.

3. The manufacturing method according to claim 2, wherein each of the heating rings is a coil, and coil axes of the coils are parallel to each other.

4. The manufacturing method according to claim 1, wherein the crystal growth furnace system comprises:
an external heating module, wherein the furnace body is movably disposed in the external heating module, wherein a distance between a top end of the external heating module and the second surface of the seed crystal opposite to the first surface is less than 80 mm.

5. The manufacturing method according to claim 4, wherein the external heating module comprises a plurality of heating rings stacked in a vertical direction, wherein a distance between a top end of the topmost one among the heating rings and the second surface is less than 80 mm in the vertical direction.

6. The manufacturing method according to claim 1, wherein an angle between the plane where the first end is located and the annular curved surface is 1 degree to 8 degrees.

7. The manufacturing method according to claim 1, wherein the ratio of the axial temperature gradient to the radial temperature gradient is 0.3 to 0.6, and the vertical distance between the plane where the first end is located and the flat surface is 1 mm to 4 mm.

8. A silicon carbide crystal boule, comprising:
a flat surface;
a truncated cone surface; and
an annular curved surface connecting the flat surface and the truncated cone surface, wherein a width of the silicon carbide crystal boule gradually decreases from a first end of the truncated cone surface connecting the annular curved surface to a second end opposite to the first end, and a vertical distance between a plane where the first end is located and the flat surface is 1 mm to 5 mm.

9. The silicon carbide crystal boule according to claim 8, wherein an angle between the plane where the first end is located and the annular curved surface is 1 degree to 8 degrees.

10. The silicon carbide crystal boule according to claim 8, wherein a width of the flat surface is 6.5 inches to 8 inches.
